(19) United States
(12) Patent Application Publication
(10) Pub. No.: US 2025/0293671 A1
(43) Pub. Date: Sep. 18, 2025

(54) ELECTRONIC CIRCUITRY, DRIVE CIRCUIT, AND CONTROL SYSTEM

(71) Applicant: Kabushiki Kaisha Toshiba, Tokyo (JP)

(72) Inventors: Shusuke KAWAI, Yokohama Kanagawa (JP); Hiroaki ISHIHARA, Yokohama Kanagawa (JP)

(21) Appl. No.: 19/065,685

(22) Filed: Feb. 27, 2025

(30) Foreign Application Priority Data
Mar. 13, 2024 (JP) 2024-039400

(51) Int. Cl. H03K 3/017; G11C 19/28; H03K 21/08

(52) U.S. Cl. CPC H03K 3/017; G11C 19/28; H03K 21/08

(57) ABSTRACT

According to one embodiment, an electronic circuitry includes a shift register circuit including a plurality of charge holding circuits; a counter circuit configured to count a number of control pulses input to the shift register circuit, which are generated based on a control signal; and a selector circuit configured to select one of outputs of the plurality of charge holding circuits based on the control signal and a count value of the counter circuit.

### CROSS REFERENCE TO RELATED APPLICATIONS

This application is based upon and claims the benefit of priority from the prior Japanese Patent Application No. 2024-039400, filed on Mar. 13, 2024, the entire contents of which are incorporated herein by reference.

### FIELD

The present embodiments relate to an electronic circuitry, a drive circuitry, and a control system.

### BACKGROUND

In the field of power electronics, semiconductor switching elements such as silicon (Si) or silicon carbide (SIC) MOSFETS (Metal Oxide Semiconductor Field Effect Transistors), IGBTs (Insulated Gate Bipolar Transistors), and GaN devices are used. In a circuit that includes these switching elements, power loss can be reduced by accelerating a switching operation of the elements. However, if the switching operation of the element is accelerated too much, noise is generated. In other words, power loss reduction and noise suppression are in a trade-off relationship.

Research is being conducted on active gate control technology as a method to optimize the above trade-off. In the active gate control technology, in order to achieve both power loss reduction and noise suppression, waveforms of drive signals at the time of turn-on and at the time of turn-off of a switching element are experimentally or theoretically determined in advance, and the waveform data is stored in an electronic circuitry. A drive circuit of the switching element generates drive signals based on the waveform data read from the electronic circuitry, and drives the switching element with that drive signals.

For example, when PWM-controlling the switching operation of the switching element, the drive circuit needs to read the waveform data from the electronic circuitry according to a PWM signal (a control signal) that instruct the switching operation.

### BRIEF DESCRIPTION OF THE DRAWINGS

FIG. 1 is a diagram illustrating a configuration of a motor control system;

FIG. 2 is a diagram illustrating a detailed configuration of a drive circuit;

FIG. 3 is a diagram illustrating an example of waveform data stored in an electronic circuitry;

FIG. 4 is a diagram illustrating an example of waveform data stored in the electronic circuitry;

FIG. 5 is a timing chart illustrating how the waveform data is output from the electronic circuitry;

FIG. 6 is a diagram illustrating a configuration of the electronic circuitry according to an embodiment 1;

FIG. 7 is a diagram illustrating a detailed configuration of a pulse counter circuit;

FIG. 8 illustrates a truth table of a selector circuit;

FIG. 9 is a timing chart explaining a normal operation of the electronic circuitry;

FIG. 10 is a diagram explaining an internal state of a shift register circuit;

FIG. 11 is a diagram explaining the internal state of the shift register circuit;

FIG. 12 is a timing chart explaining an operation when an abnormal pulse is generated in the electronic circuitry;

FIG. 13 is a diagram explaining the internal state of the shift register circuit;

FIG. 14 is a diagram explaining the internal state of the shift register circuit;

FIG. 15 is a diagram illustrating a configuration of an electronic circuitry according to an embodiment 2;

FIG. 16 is a diagram illustrating a detailed configuration of a correction circuit;

FIG. 17 is a diagram illustrating a truth table of the selector circuit;

FIG. 18 is a timing chart explaining the operation when an abnormal pulse is generated in the electronic circuitry;

FIG. 19 is a diagram explaining the internal state of the shift register circuit;

FIG. 20 is a diagram explaining the internal state of the shift register circuit;

FIG. 21 is a diagram explaining the internal state of the shift register circuit;

FIG. 22 is a diagram illustrating a configuration of an electronic circuitry according to an embodiment 3;

FIG. 23 is a diagram illustrating a detailed configuration of the correction circuit;

FIG. 24 is a timing chart explaining the operation when an abnormal pulse is generated in the electronic circuitry;

FIG. 25 is a diagram explaining the internal state of the shift register circuit; and

FIG. 26 is a diagram explaining the internal state of the shift register circuit.

### DETAILED DESCRIPTION

According to one embodiment, an electronic circuitry includes a shift register circuit including a plurality of charge holding circuits; a counter circuit configured to count a number of control pulses input to the shift register circuit, which are generated based on a control signal; and a selector circuit configured to select one of outputs of the plurality of charge holding circuits based on the control signal and a count value of the counter circuit.

According to one embodiment, an electronic circuitry includes: a shift register circuit including N charge holding circuits; a correction circuit configured to generate correction pulses and to output the correction pulses to the shift register circuit; and a counter circuit configured to count a sum of a number of control pulses input to the shift register circuit and a number of the correction pulses, the control pulses being generated based on a control signal. The counter circuit counts N integer values. The correction circuit is configured to start outputting the correction pulses in response to the state of the control signal changing and continue to output the correction pulses until a count value of the counter circuit returns to an initial value.

According to one embodiment, a drive circuit includes a pulse generation circuit configured to generate and output control pulses based on a control signal; an electronic circuitry configured to sequentially receive the control pulses and to sequentially output waveform data in synchronization with the control pulses; and a signal generation circuit configured to generate a drive signal of a switching element based on the waveform data. The electronic circuitry includes a shift register circuit including a plurality of charge holding circuits, a counter circuit configured to count a number of the control pulses input to the shift register circuit, and a first selector circuit configured to select one of outputs of the plurality of charge holding circuits based on the control signal and a count value of the counter circuit.

According to one embodiment, a control system includes a pulse generation circuit configured to generate and output control pulses based on a control signal; a plurality of electronic circuitries configured to sequentially receive the control pulses and to sequentially output waveform data in synchronization with the control pulses; a second selector circuit configured to input the control pulses output from the pulse generation circuit to one of the plurality of electronic circuitries based on a selection signal; a third selector circuit configured to acquire the waveform data output from one of the plurality of electronic circuitries based on the selection signal; a signal generation circuit configured to generate a drive signal of a switching element based on the waveform data acquired by the third selector circuit; a detection circuit configured to detect an operating state of the switching element; and a control circuit configured to generate the control signal and the selection signal based on the operating state. The electronic circuitry includes a shift register circuit including a plurality of charge holding circuits, a counter circuit configured to count a number of the control pulses input to the shift register circuit, and a first selector circuit configured to select one of outputs of the plurality of charge holding circuits based on the control signal and a count value of the counter circuit.

Hereinafter, the present embodiment will be described with reference to the drawings. In the drawings, same reference signs are assigned to same or corresponding elements, and detailed descriptions are omitted as appropriate.

### Embodiment 1

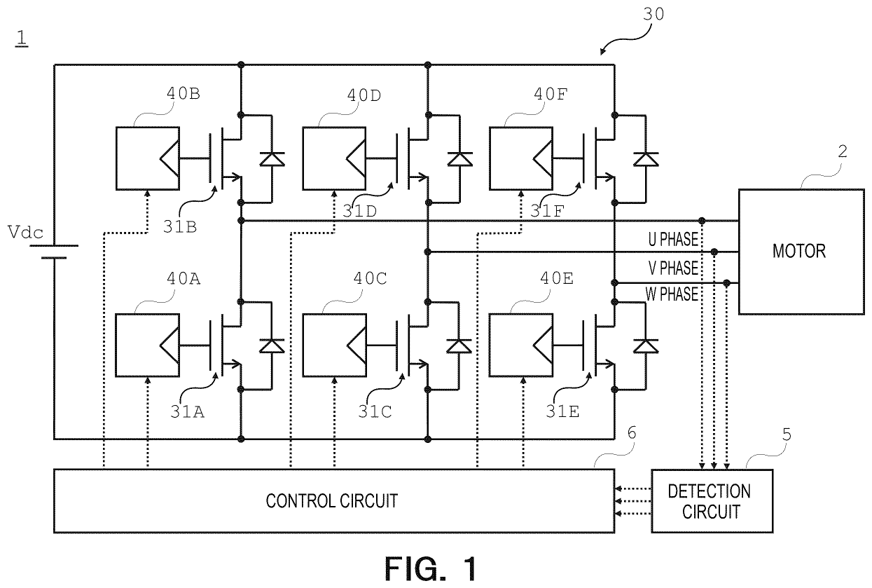

FIG. 1 is a diagram illustrating a configuration of a motor control system 1 according to the embodiment 1. The motor control system 1 includes a three-phase AC motor 2 as a load, a DC power supply Vdc, switching elements 31A-31F forming a three-phase inverter circuit 30, and drive circuits 40A-40F that drive the switching elements 31A-31F, respectively. In addition, the motor control system 1 includes a detection circuit 5 that detects operating states of the switching elements 31A-31F, and a control circuit 6 that controls the drive circuits 40A-40F.

The switching element 31A and the switching element 31B are N-channel MOSFETs. By the switching element 31A and the switching element 31B, an arm pair of a U phase of the inverter circuit 30 is formed. The drive circuit 40A controls switching operations, namely turn-on and 20 turn-off, of the switching element 31A by controlling a gate current as a drive signal of the switching element 31A. The drive circuit 40B controls the switching operations, namely the turn-on and the turn-off, of the switching element 31B by controlling the gate current as the drive signal of the switching element 31B.

Similarly, the switching element 31C and the switching element 31D are N-channel MOSFETs. By the switching element 31C and the switching element 31D, an arm pair of a V phase of the inverter circuit 30 is formed. The drive circuit 40C controls the switching operations of the switching 30 element 31C by controlling the drive signal of the switching element 31C. The drive circuit 40D controls the switching operations of the switching element 31D by controlling the drive signal of the switching element 31D.

Similarly, the switching element 31E and the switching element 31F 35 are N-channel MOSFETs. By the switching element 31E and the switching element 31F, an arm pair of a W phase of the inverter circuit 30 is formed.

The drive circuit 40E controls the switching operations of the switching element 31E by controlling the drive signal of the switching element 31E. The drive circuit 40F controls the switching operations of the switching element 31F by controlling the drive signal of the switching element 31F.

The detection circuit 5 detects the operating states of the switching elements 31A-31F based on respective current values of the U phase, the V phase, and the W phase of the motor 2, and transmits the operating states to the control circuit 6. Alternatively, the detection circuit 5 may detect the operating states of the switching elements 31A-31F based on temperature information obtained by an unillustrated temperature sensor built in the motor 2. Alternatively, the detection circuit 5 may detect the operating states of the switching elements 31A-31F based on signals received from an unillustrated control microcomputer.

The control circuit 6 supplies PWM signals as control signals to control the switching operations of the switching elements 31A-31F, selection signals that select waveform data of the drive signals of the switching elements 31A-31F, and clock signals, respectively, to the drive circuits 40A-40F, based on the operating states of the switching elements 31A-31F received from the detection circuit 5.

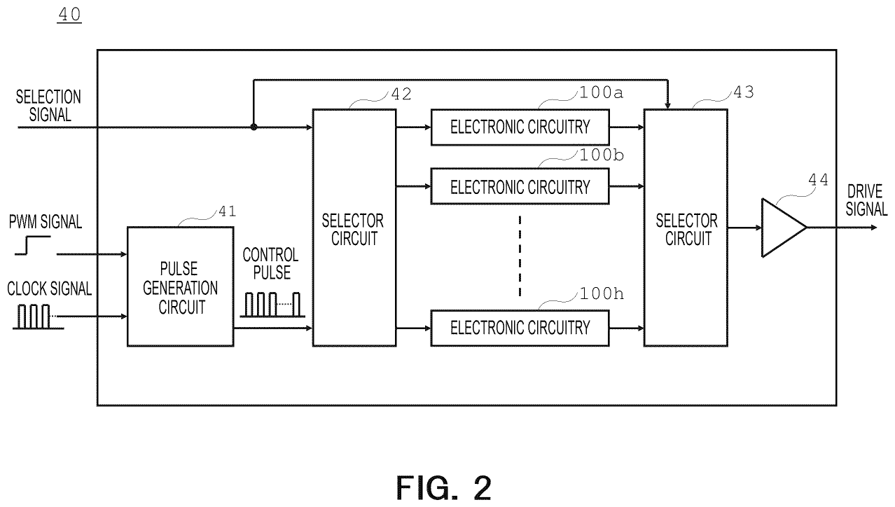

FIG. 2 is a diagram illustrating a detailed configuration of a drive circuit 40. Since the configurations of the drive circuits 40A-40F are all the same, they are collectively described as the drive circuit 40 hereinafter. The drive circuit 40 includes a pulse generation circuit 41, eight electronic circuitries 100a-100h, a selector circuit 42, a selector circuit 43, and a signal generation circuit 44.

The pulse generation circuit 41 generates and outputs N=32 control pulses synchronized with the clock signal according to a rising edge and a falling edge of the PWM signal supplied from the control circuit 6. In detail, the pulse generation circuit 41 starts outputting the control pulses synchronized with the clock signals when the rising edge of the PWM signal is detected. In this case, if a length of high-level PWM signal is sufficient, 32 control pulses are output. However, if the length of the PWM signal is insufficient, for example, if the length is shorter than time of 32 clock signals, the output of the control pulses may be stopped at a time point at which the control pulses fewer than 32 are output. In addition, the pulse generation circuit 41 starts outputting the control pulses synchronized with the clock signals when the falling edge of the PWM signal is detected. In this case, if the length of low-level PWM signal is sufficient, 32 control pulses are output. However, if the length of the low-level PWM signal is insufficient, for example, if the length is shorter than the time of 32 clock signals, the output of the control pulses may be stopped at the time point at which the control pulses fewer than 32 are output.

However, the configuration of the pulse generation circuit 41 is not particularly limited to the above configuration. As an example, it is also possible to adopt the configuration described in Japanese Patent Laid-Open No. 2024-022328. Further, in the present embodiment 1, a value of N is not limited to 32. In the present embodiment 1, the value of N may be any integer greater than or equal to 1, that is, a positive integer.

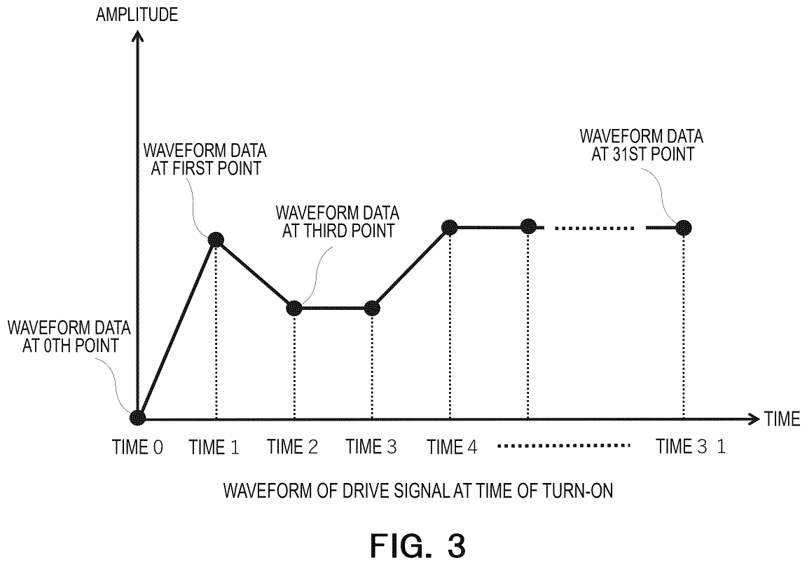

The electronic circuitries 100a-100h all have the same configuration and, as will be described in detail later, include 12 shift register circuits of N=32 bits. The electronic circuitry 100a stores the waveform data for which a waveform of the drive signal at the time of the turn-on of the switching element 31, which is theoretically or experimentally determined in advance, is sampled in a time direction at 32 points in a sampling cycle Tc and is quantized in an amplitude direction with 12 bits (see FIG. 3). That is, the electronic circuitry 100a stores the waveform data for 32 points quantized with 12 bits.

The electronic circuitries 100b-100d also store the waveform data of different versions of the drive signal at the time of the turn-on of the switching element 31, respectively. Therefore, the drive circuit 40 holds four types of the waveform data as the waveform of the drive signal at the time of the turn-on of the switching element 31. However, the number of pieces of the waveform data at the time of the turn-on held by the drive circuit 40 is not limited to four. By appropriately adjusting the number of electronic circuitries 100 and a bit number of the selection signal the drive circuit 40 can hold an arbitrary number of pieces of the waveform data.

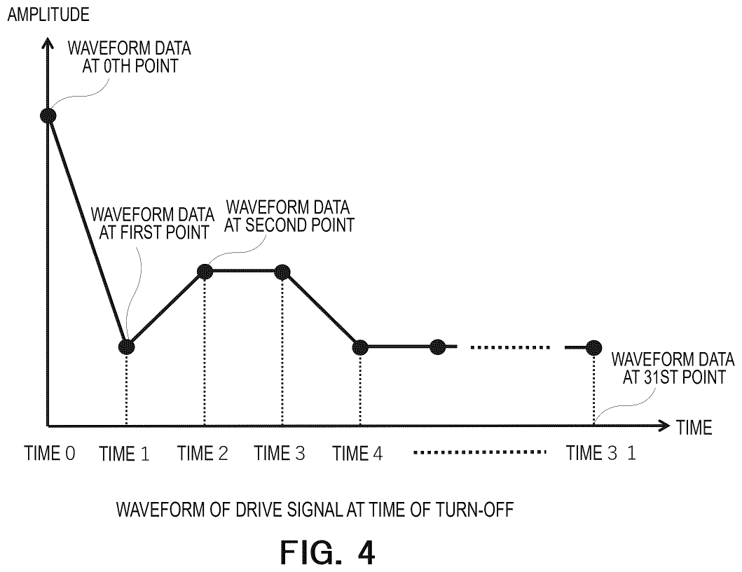

Similarly, the electronic circuitry 100e stores the waveform data for which the waveform of the drive signal at the time of the turn-off of the switching element 31, which is theoretically or experimentally determined in advance, is sampled in the time direction at 32 points in the sampling cycle Tc and is quantized in the amplitude direction with 12 bits (see FIG. 4). That is, the electronic circuitry 100e stores the waveform data for 32 points quantized with 12 bits.

The electronic circuitries 100f-100h also store the waveform data of different versions of the drive signal at the time of the turn-off of the switching element 31, respectively. Therefore, the drive circuit 40 holds four types of the waveform data as the waveform of the drive signal at the time of the turn-off of the switching element 31. However, the number of pieces of the waveform data at the time of the turn-off held by the drive circuit 40 is not limited to four. By appropriately adjusting the number of the electronic circuitries 100 and the bit number of the selection signal, the drive circuit 40 can hold an arbitrary number of pieces of the waveform data.

The selector circuit 42 supplies the control pulses output from the pulse generation circuit 41 to one of the electronic circuitries 100a-100h, based on the selection signal supplied from the control circuit 6.

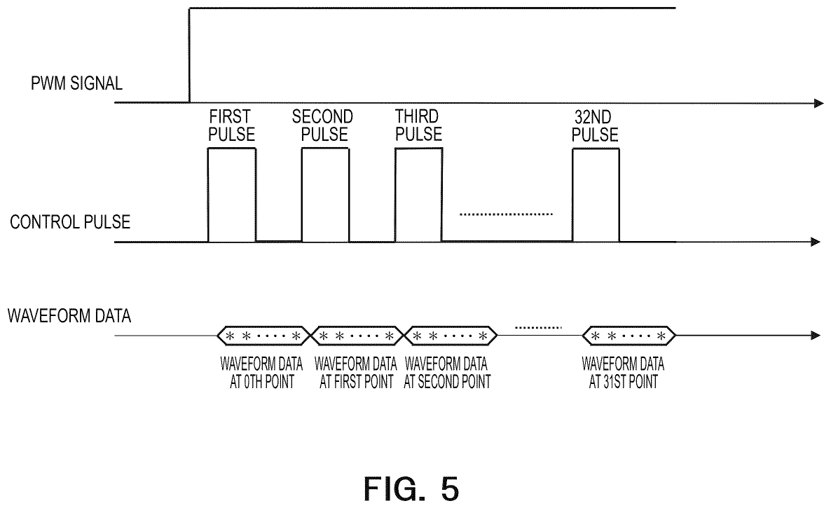

When the control pulses are sequentially input to one of the electronic circuitries 100a-100h, the waveform data for 32 points quantized with 12 bits is sequentially output from the electronic circuitry 100 that has received the control pulses, in synchronization with each control pulse. That is, from the electronic circuitry 100, the waveform data for one point quantized with 12 bits is output every time one control pulse is input, and the waveform data for a total of 32 points is sequentially output (see FIG. 5).

The selector circuit 43 sequentially supplies, to the signal generation circuit 44, the waveform data for 32 points sequentially output from the electronic circuitry 100 that has received the control pulses, based on the selection signal supplied from control circuit 6.

The signal generation circuit 44 functions as a D/A converter with a 12-bit input, and generates the drive signal (analog signal) for the switching element 31 based on the waveform data (digital signal) for 32 points quantized with 12 bits and sequentially supplied from the selector circuit 43. The generated drive signal has a waveform that connects respective sampling points in FIG. 3 or FIG. 4 for example, and is supplied to the switching element 31.

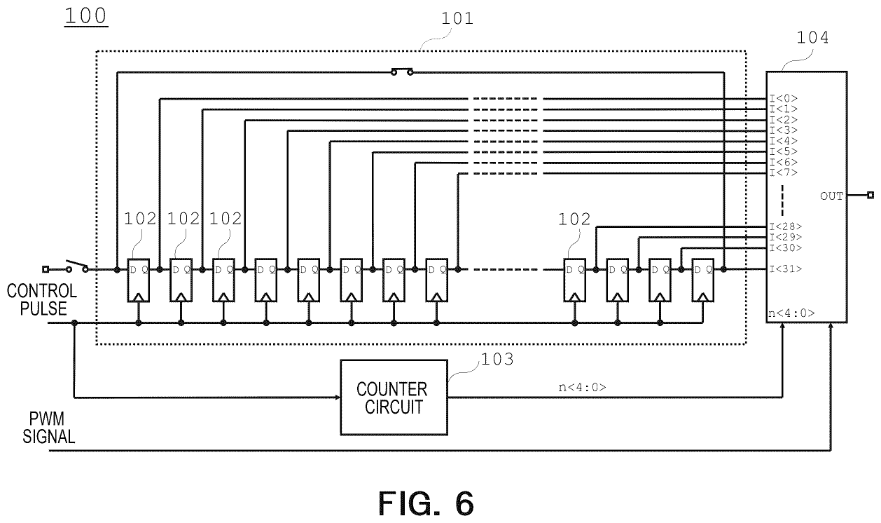

FIG. 6 is a diagram illustrating a detailed configuration of the electronic circuitry 100. As described earlier, since the configurations of the electronic circuitries 100a-100h are all the same, they are collectively described as the electronic circuitry 100. In addition, the actual electronic circuitry 100 includes 12 each of components 101, 103, and 104 illustrated in FIG. 6, all connected in same topology. However, in order to simplify the description, only one representative of each component is illustrated in FIG. 6.

The electronic circuitry 100 includes a 32-bit shift register circuit 101, a counter circuit 103, and a selector circuit 104. The shift register circuit 101 is formed by cascade-connecting N=32 D flip-flops (D-FFs) 102. To a clock terminal of each D-FF 102 as a charge holding circuit, the control pulses supplied from the pulse generation circuit 41 are input. The counter circuit 103 counts the number of the control pulses input to the shift register circuit 101. The selector circuit 104 selects one of outputs of the 32 D-FFs 102 to be its own output OUT, based on the PWM signal and a count value of the counter circuit 103.

The shift register circuit 101 has a cyclic configuration. In detail, in the shift register circuit 101, to a D input of a 0th D-FF 102 (the leftmost D-FF in the figure), a Q output of a 31st D-FF 102 (the rightmost D-FF in the figure) is connected. As a result, every time the control pulse is input to the clock terminal of each D-FF 102, data held in each D-FF 102 shifts in a circular manner in a right direction in the figure, and returns to an initial state after 32 control pulses are input.

The output of each D-FF 102 is connected to the selector circuit 104. In detail, the output of the 0th D-FF 102 is connected to a 0th input port I<0> of the selector circuit 104. The output of a first D-FF 102 is connected to a first input port I<1> of the selector circuit 104. Similarly, the output of the 31st D-FF 102 is connected to a 31st input port I<31> of the selector circuit 104.

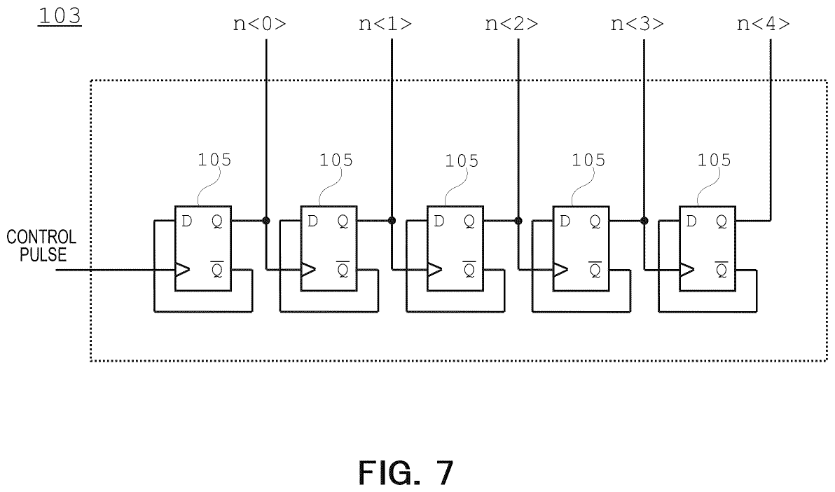

FIG. 7 is a diagram illustrating a detailed configuration of the counter circuit 103. The counter circuit 103 is formed by cascade-connecting five D-FFs 105 in which a D input and an inverted Q output are connected. As a result, the counter circuit 103 can count N integer values from 0 to N-1, specifically 32 integer values from 0 to 31.

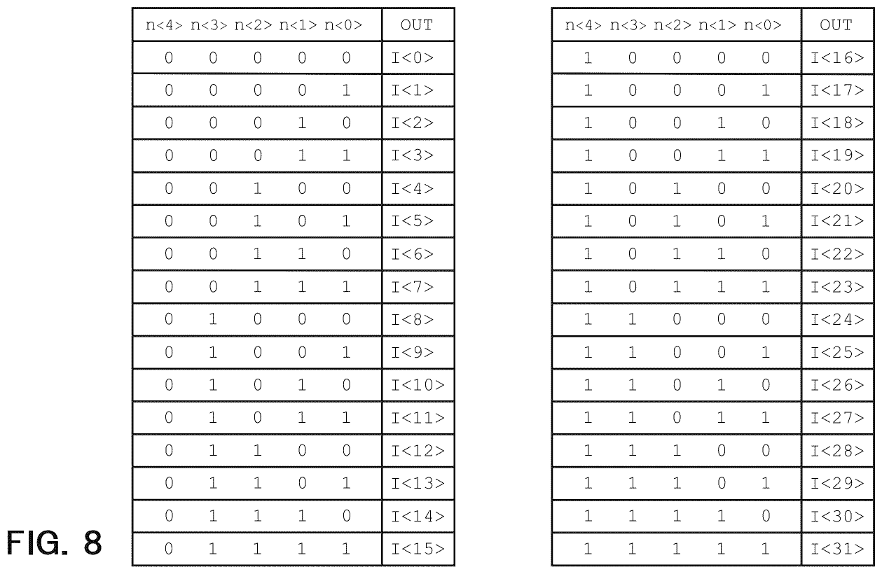

FIG. 8 is a diagram illustrating a truth table of the selector circuit 104. To the selector circuit 104, all bits (n<4: 0>) of the count value of the counter circuit 103 are input. The selector circuit 104 selects one of the outputs of the D-FFs 102 included in the shift register circuit 101 to be its own output OUT according to the truth table in FIG. 8, based on the count value of the counter circuit 103 at a timing at which the rising edge or the falling edge of the PWM signal is detected.

In detail, the selector circuit 104 included in the electronic circuitries 100a-100d storing the waveform data at the time of the turn-on of the switching element 31 selects one of the outputs of the D-FFs 102 included in the shift register circuit 101 to be its own output OUT according to the truth table in FIG. 8, based on the count value of the counter circuit 103 at the timing at which the “rising edge” of the PWM signal is detected.

On the other hand, the selector circuit 104 included in the electronic circuitries 100e-100h storing the waveform data at the time of the turn-off of the switching element 31 selects one of the outputs of the D-FFs 102 included in the shift register circuit 101 to be its own output OUT according to the truth table in FIG. 8, based on the count value of the counter circuit 103 at the timing at which the “falling edge” of the PWM signal is detected.

An operation of the selector circuit 104 included in the electronic circuitries 100a-100e and an operation of the selector circuit 104 included in the electronic circuitries 100f-100h are all the same except for a difference between switching its own output OUT at the rising edge or at the falling edge of the PWM signal. Therefore, hereinafter, the selector circuit 104 will be described as switching its own output OUT at the rising edge of the PWM signal.

Next, the operation of the electronic circuitry 100 according to the present embodiment 1 will be described separately for a normal operation and an operation when an unintended abnormal pulse is generated in the PWM signal. Causes of the unintended abnormal pulse in the PWM signal include, for example, sudden change in a duty ratio of the PWM signal and influence of noise generated when the duty ratio of the PWM signal is high.

### (Normal Operation)

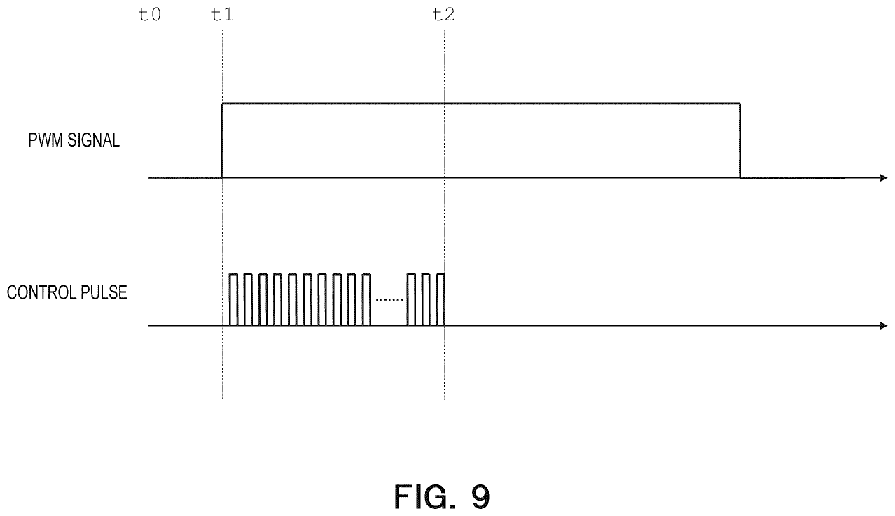

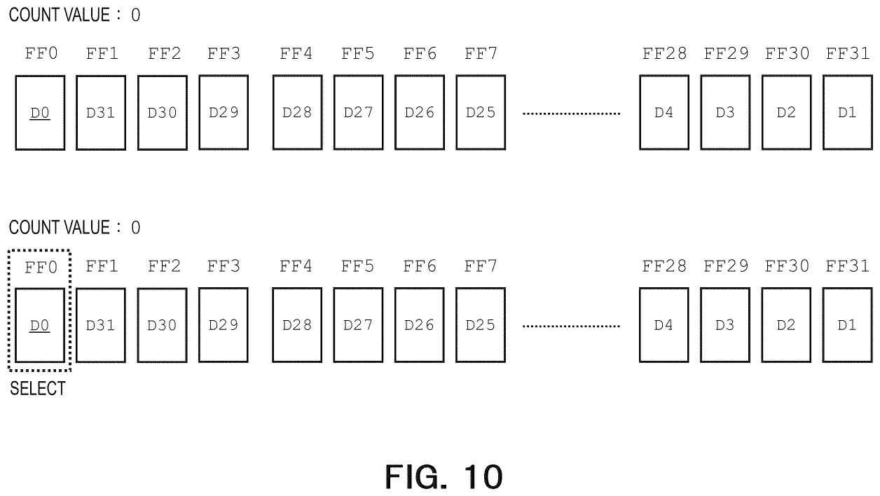

In the initial state at a time to in FIG. 9, the shift register circuit 101 of the electronic circuitry 100 stores N=32 pieces of data (D0, D1, . . . . D31) in a predetermined order. An upper part of FIG. 10 illustrates an internal state of the shift register circuit 101 in the initial state at the time to. The 0th D-FF (FF0) holds 0th data DO. The first D-FF (FF1) holds 31st data D31. Similarly, the 31st D-FF (FF31) holds first data D1.

At a time t1 in FIG. 9, when the rising edge of the PWM signal is detected, the pulse generation circuit 41 starts outputting the control pulses. When the input of the control pulses from the pulse generation circuit 41 is started, the electronic circuitry 100 starts outputting the data stored in its own shift register circuit 101. In detail, the selector circuit 104 selects one of the outputs of the D-FFs 102 included in the shift register circuit 101 to be its own output OUT according to the truth table in FIG. 8, based on the count value of the counter circuit 103 at the timing at which the rising edge of the PWM signal is detected.

Specifically, at the time t1, since the count value of the counter circuit 103 is 0 (n<4>=n<3>=n<2>=n<1>=n<0>=0), the selector circuit 104 selects the output of the 0th D-FF 102 connected to its own 0th input port I<0> to be its own output OUT. A lower part of FIG. 10 illustrates the count value of the counter circuit 103 and the internal state of the shift register circuit 101 at the time t1. From this point on, every time the control pulse is input from the pulse generation circuit 41, the data stored in the shift register circuit 101 is output piece by piece from the electronic circuitry 100 in the predetermined order (D0, D1, . . . . D31).

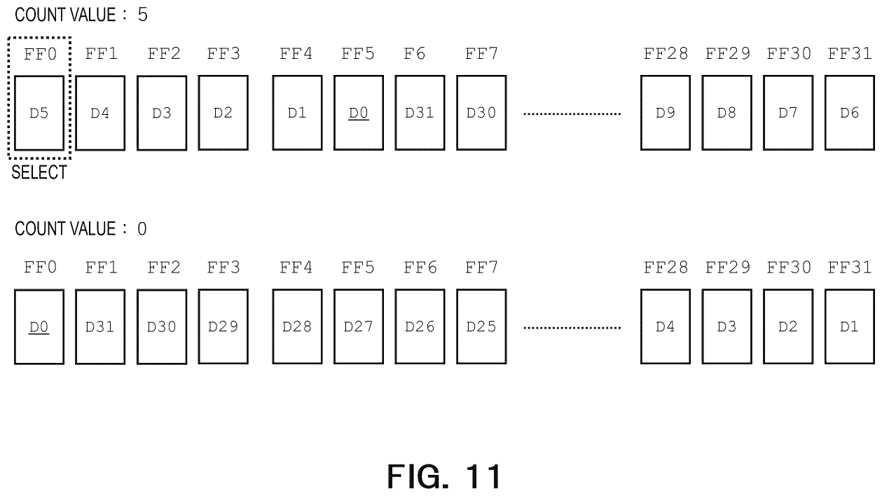

An upper part of FIG. 11 illustrates the count value of the counter circuit 103 and the internal state of the shift register circuit 101 at the time point at which five control pulses are input. Since the shift register circuit 101 has the cyclic configuration, the pieces of already output data DO-D4 are stored again in FF5-FF1.

At a time t2 in FIG. 9, the pulse generation circuit 41 completes the output of the 32 control pulses. The electronic circuitry 100 completes the output of the 32 pieces of data. A lower part of FIG. 11 illustrates the count value of the counter circuit 103 and the internal state of the shift register circuit 101 at the time point at which the output of the 32 pieces of data is completed. Since the shift register circuit 101 has the cyclic configuration, the internal state when the output of the 32 pieces of data is completed (the lower part of FIG. 11) is the same as the internal state in the initial state (the upper part of FIG. 10). In addition, the count value of the counter circuit 103 returns to 0 after counting the 32 control pulses.

(Operation when Unintended Abnormal Pulse is Generated in PWM Signal)

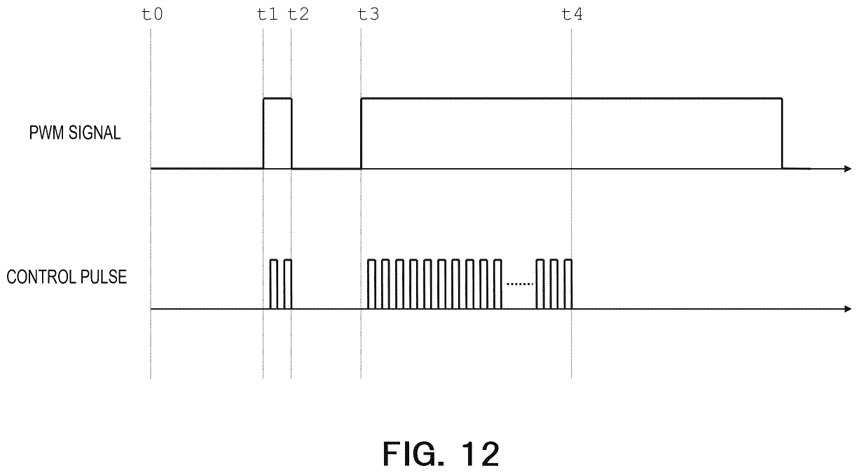

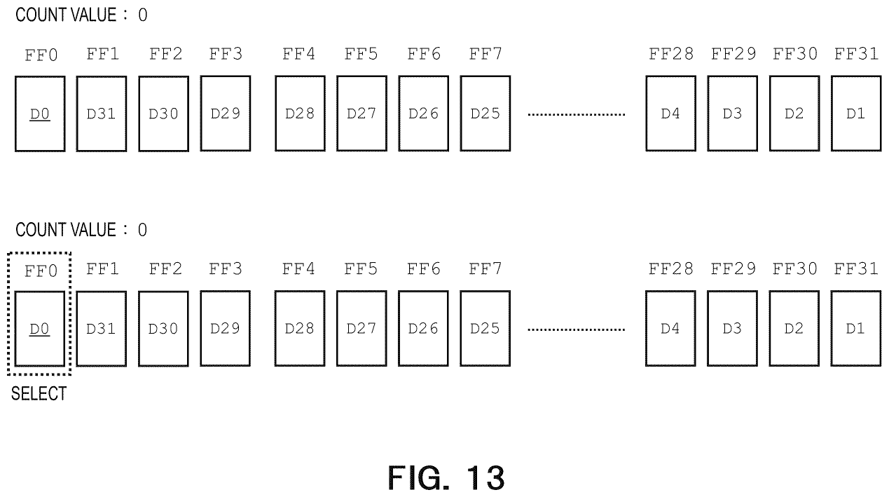

In the initial state at the time to in FIG. 12, the shift register circuit 101 of the electronic circuitry 100 stores the 32 pieces of data (D0, D1, . . . . D31) in the predetermined order. An upper part of FIG. 13 illustrates the count value of the counter circuit 103 and the internal state of the shift register circuit 101 in the initial state at the time to.

At the time t1 in FIG. 12, when the rising edge (false rising edge) of the PWM signal due to an unintended abnormal pulse is detected, the pulse generation circuit 41 starts outputting the control pulses. When the input of the control pulses from the pulse generation circuit 41 is started, the electronic circuitry 100 starts outputting the data stored in its own shift register circuit 101.

In detail, at the time t1, since the count value of the counter circuit 103 is 0, the selector circuit 104 selects the output of the 0th D-FF 102 connected to its own 0th input port I<0> to be its own output OUT. A lower part of FIG. 13 illustrates the count value of the counter circuit 103 and the internal state of the shift register circuit 101 at the time t1. From this point on, every time the control pulse is input from the pulse generation circuit 41, the data stored in the shift register circuit 101 is output piece by piece from the electronic circuitry 100 in the predetermined order (D0, D1, . . . ).

At the time t2 in FIG. 12, when the falling edge of the PWM signal is detected, the pulse generation circuit 41 starts outputting the control pulses again from that timing. However, the control pulses output at this time are input not to the electronic circuitry 100 currently being described but to a different electronic circuitry that stores the waveform data at the time of the turn-off. In FIG. 12, the control pulse output at the falling edge of the PWM signal is omitted.

At a time t3 in FIG. 12, when the rising edge (true rising edge) of the PWM signal is detected again, the pulse generation circuit 41 starts outputting the control pulses again from that timing. When the input of the control pulses from the pulse generation circuit 41 is started again, the electronic circuitry 100 starts outputting the data stored in its own shift register circuit 101 again.

At this time, the electronic circuitry 100 does not start outputting from continuation of the already output data, and outputs the 32 pieces of data in the predetermined order (D0, D1, . . . . D31) from the beginning again.

For example, at the time t3, if the count value of the counter circuit 103 is 2 (n<4>=0, n<3>=0, n<2>=0, n<1>=1, n<0>=0), the selector circuit 104 selects the output of the second D-FF 102 connected to its own second input port I<2> to be its own output OUT according to the truth table in FIG. 8.

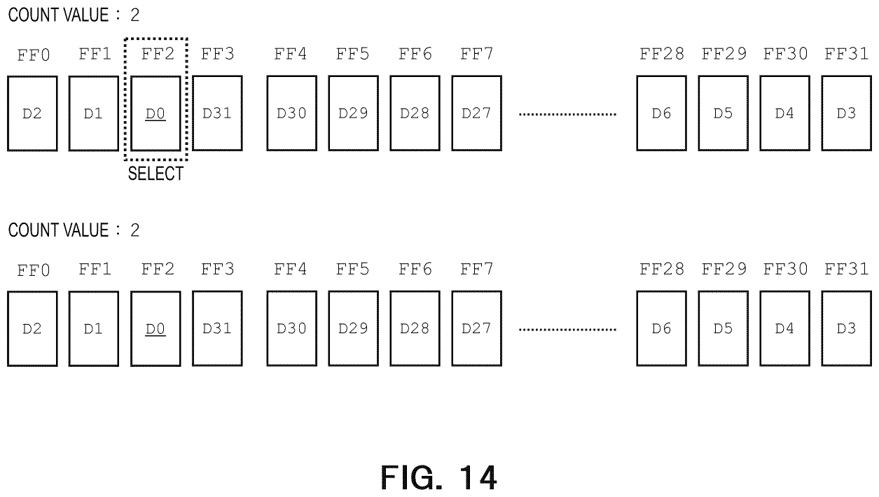

An upper part of FIG. 14 illustrates the count value of the counter circuit 103 and the internal state of the shift register circuit 101 at the time t3. As described above, since the selector circuit 104 selects the output of the second D-FF (FF2), the output of the FF2 becomes the output of the electronic circuitry 100. From this point on, the output of the FF2 changes in the order of D0, D1, . . . , D31 every time the control pulse is input. Therefore, every time the control pulse is input from the pulse generation circuit 41, the 32 pieces of data stored in the shift register circuit 101 are output piece by piece from the electronic circuitry 100 in the predetermined order (D0, D1, . . . . D31).

At a time t4 in FIG. 12, the pulse generation circuit 41 completes the output of the 32 control pulses. The electronic circuitry 100 completes the output of the 32 pieces of data. A lower part of FIG. 14 illustrates the count value of the counter circuit 103 and the internal state of the shift register circuit 101 at the time point at which the output of the 32 pieces of data is completed.

In this state, the count value of the counter circuit 103 is 2 and corresponds to the FF2 holding leading data DO. Therefore, without resetting the counter circuit 103, it is possible to cope with the input of the next and subsequent control pulses in this state. In other words, there is no need to provide a reset mechanism in the counter circuit 103. As described above, the electronic circuitry 100 according to the present embodiment 1 includes the shift register circuit 101 including the plurality of D-FFs 102, the counter circuit 103 that counts the number of the control pulses generated based on the PWM signal and input to the shift register circuit 101, and the selector circuit 104 that selects one of the outputs of the plurality of D-FFs 102 based on the PWM signal and the count value of the counter circuit 103.

Due to the above characteristics, the electronic circuitry 100 according to the present embodiment 1 can output the stored data in the predetermined order (D0, D1, . . . . D31) at all times when the input of the control pulses generated based on the PWM signal is started, even if an unintended abnormal pulse is generated in the PWM signal.

Further, in the electronic circuitry 100 according to the present embodiment 1, all the outputs of the N=32 D-FFs 102 are connected to the selector circuit 104. Thus, no matter at what timing the input of the control pulse is interrupted, it is possible to cope with the input of the next and subsequent control pulses according to the internal state of the shift register circuit 101 at that timing.

In addition, the drive circuit 40 according to the present embodiment 1 includes the pulse generation circuit 41 that generates and outputs the control pulses based on the PWM signal, the electronic circuitry 100 that sequentially receives the control pulses and sequentially outputs the waveform data in synchronization with the control pulses, and the signal generation circuit 44 that generates the drive signal of the switching element 31 based on the waveform data.

Due to the above characteristics, in order to achieve both power loss reduction and noise suppression, the waveform of the drive signal of the switching element 31 can be experimentally or theoretically determined in advance, and such waveform data can be stored in the electronic circuitry 100. The drive circuit 40 can generate the drive signal based on the waveform data stored in the electronic circuitry 100 and drive the switching element 31 with that drive signal. In this case, even if a true rising pulse follows an unintended abnormal pulse generated in the PWM signal, the waveform data is output from the electronic circuitry 100 in the predetermined order (D0, D1, . . . . D31) at all times.

In addition, the drive circuit 40 according to the present embodiment 1 includes the plurality of electronic circuitries 100a-100h, the selector circuit 42 that inputs the control pulses output from the pulse generation circuit 41 to one of the plurality of electronic circuitries 100a-100h based on the selection signal, and the selector circuit 43 that inputs the waveform data output from one of the plurality of electronic circuitries 100a-100h to the signal generation circuit 44 based on the selection signal. Due to such characteristics, it is possible to select one from the plurality of pieces of waveform data and generate the drive signal of the switching element 31 based on the selected waveform data.

Furthermore, the motor control system 1 according to the present embodiment 1 includes the drive circuit 40, the detection circuit 5 that detects the operating state of the switching element 31, and the control circuit 6 that generates the PWM signal and the selection signal based on the operating state. Due to such characteristics, the motor control system 1 according to the present embodiment 1 can generate an optimal drive signal that achieves both power loss reduction and noise suppression based on the operating state of the switching element 31, and drive the switching element 31 with that drive signal.

### Embodiment 2

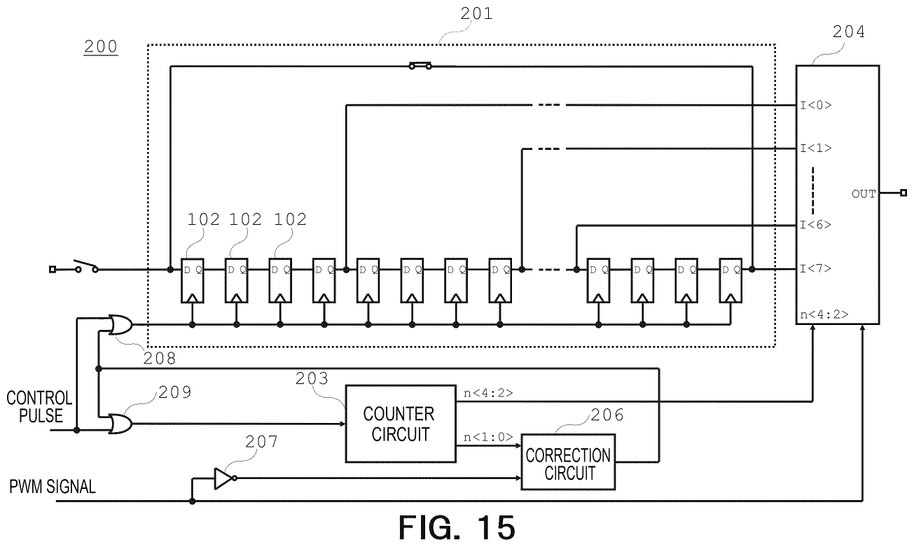

FIG. 15 is a diagram illustrating a configuration of an electronic circuitry 200 according to the embodiment 2. The electronic circuitry 200 includes a 32-bit shift register circuit 201, a counter circuit 203, a selector circuit 204, and a correction circuit 206. The correction circuit 206 generates and outputs correction pulses based on the PWM signal inverted by a NOT gate 207 and the count value of the counter circuit 203.

The shift register circuit 201 is formed by cascade-connecting the N=32 D-FFs 102. To the shift register circuit 201, the control pulses output from the pulse generation circuit 41 and the correction pulses output from the correction circuit 206 are both input via an OR gate 208. In the embodiment 1 described earlier, the outputs of all the D-FFs 102 included in the shift register circuit 101 are connected to the selector circuit 104. In contrast, in the present embodiment 2, out of the N=32 D-FFs 102 included in the shift register circuit 201, M=4 are grouped together, and only the output of one from each group of four is connected to the selector circuit 204.

Specifically, the 0th to third D-FFs 102 are grouped together, and only the output of the third D-FF 102 from them is connected to the 0th input port I<0> of the selector circuit 204. Next, fourth to seventh D-FFS 102 are grouped together, and only the output of the seventh D-FF 102 from them is connected to the first input port I<1> of the selector circuit 204. Similarly, 28th to 31st D-FFs 102 are grouped together, and only the output of the 31st D-FF 102 from them is connected to a seventh input port I<7> of the selector circuit 204.

In the present embodiment 2, the values of N and M are not limited to 32 and 4. In the present embodiment 2, M may be a positive integer, and N may be a multiple of M.

The detailed configuration of the counter circuit 203 is the same as that of the counter circuit 103 in the embodiment 1 (see FIG. 7). To the counter circuit 203, the control pulses output from the pulse generation circuit 41 and the correction pulses output from the correction circuit 206 are both input via an OR gate 209. Thus, the counter circuit 203 counts not only the number of the control pulses input to the shift register circuit 201 but also the number of the correction pulses input to the shift register circuit 201. In other words, the counter circuit 203 counts a sum of the number of the control pulses and the number of the correction pulses input to the shift register circuit 201.

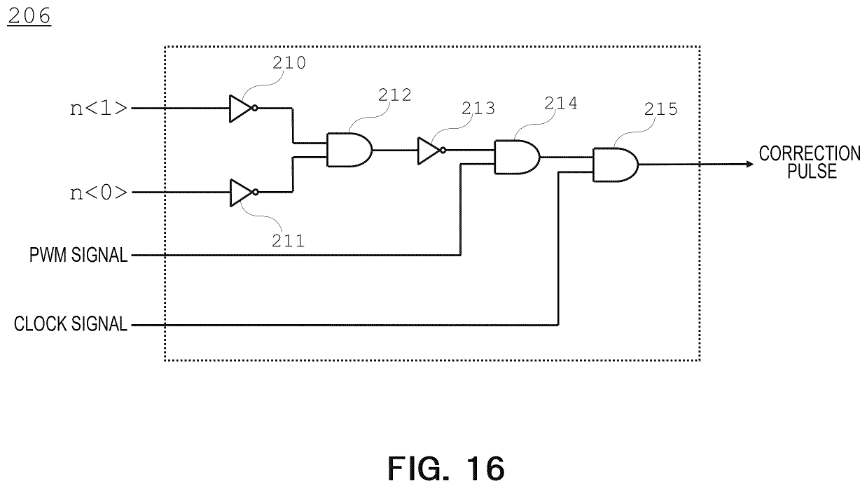

FIG. 16 is a diagram illustrating a detailed configuration of the correction circuit 206. The correction circuit 206 receives lower two bits (n<1: 0>) of the count value of the pulse counter circuit 203, the PWM signal, and the clock signals same as those input to the pulse generation circuit 41 (see FIG. 2). The correction circuit 206 is formed of NOT gates 210 and 211, an AND gate 212, a NOT gate 213, an AND gate 214, and an AND gate 215. With such a configuration, the correction circuit 206 starts outputting the correction pulses when the “falling edge” of the PWM signal is detected, and continues to output the correction pulses until the count value of the counter circuit 203 becomes a multiple of M=4.

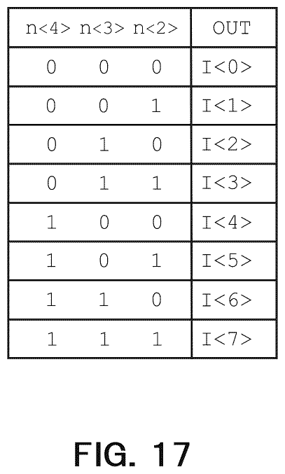

FIG. 17 is a diagram illustrating a truth table of the selector circuit 204. To the selector circuit 204, upper three bits (n<4: 2>) of the count value of the counter circuit 203 are input. The selector circuit 204 selects one of the outputs of the D-FFs 102 corresponding to a multiple of M=4 included in the shift register circuit 201 to be its own output OUT according to the truth table in FIG. 17, based on the upper three bits (n<4: 2>) of the count value of the counter circuit 203 at the timing at which the rising edge of the PWM signal is detected.

Next, the operation when an unintended abnormal pulse is generated in the PWM signal in the electronic circuitry 200 according to the present embodiment 2 will be described. The normal operation is the same as that in the embodiment 1 described earlier so that the description is omitted.

(Operation when Unintended Abnormal Pulse Is Generated in PWM signal)

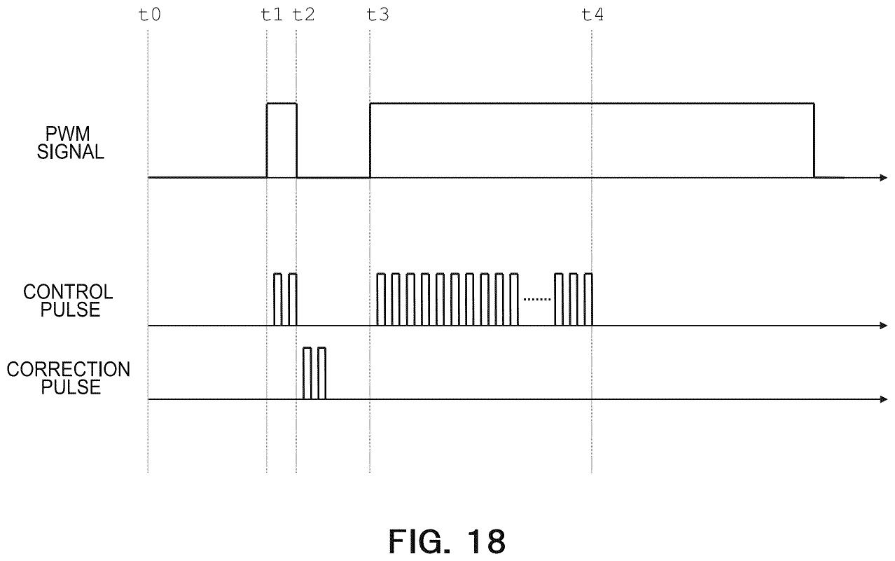

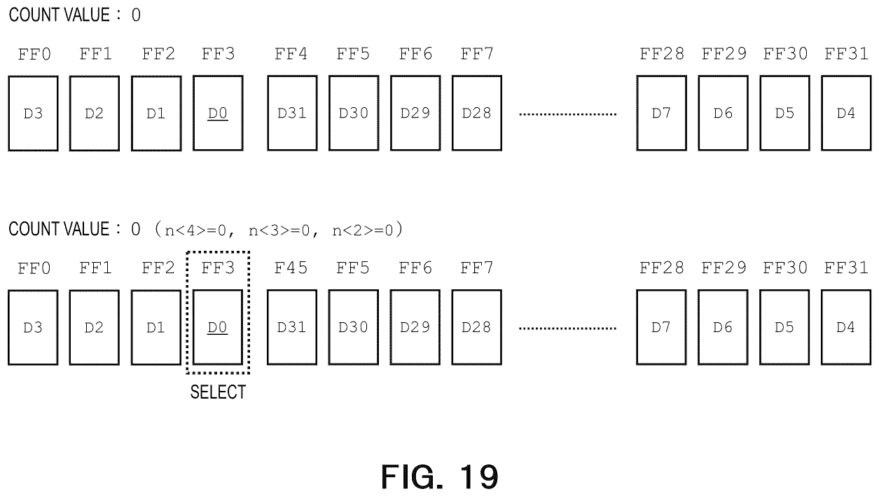

In the initial state at the time to in FIG. 18, the shift register circuit 201 of the electronic circuitry 200 stores the 32 pieces of data (D0, D1, . . . D31) in the predetermined order. An upper part of FIG. 19 illustrates the count value of the pulse counter circuit 203 and the internal state of the shift register circuit 201 in the initial state at the time to.

At the time t1 in FIG. 18, when the rising edge (false rising edge) of the PWM signal due to an unintended abnormal pulse is detected, the pulse generation circuit 41 starts outputting the control pulses. When the input of the control pulses from the pulse generation circuit 41 is started, the electronic circuitry 200 starts outputting the data stored in the shift register circuit 201.

Specifically, at the time t1, the count value of the counter circuit 203 is 0, and its upper three bits are n<4>=n<3>=n<2>=0. Therefore, the selector circuit 204 selects the output of the third D-FF connected to its own 0th input port I<0> to be its own output OUT according to the truth table in FIG. 17. A lower part of FIG. 19 illustrates the count value of the counter circuit 203 and the internal state of the shift register circuit 201 at the time t1. From this point on, every time the control pulse is input from the pulse generation circuit 41, the data stored in the shift register circuit 201 is output piece by piece from the electronic circuitry 200 in the predetermined order (D0, D1, . . . ).

At the time t2 in FIG. 18, when the falling edge of the PWM signal is detected, the pulse generation circuit 41 starts outputting the control pulses again from that timing. However, the control pulses output at this time are input not to the electronic circuitry 200 currently being described but to a different electronic circuitry that stores the waveform data at the time of the turn-off. In FIG. 18, the control pulse output at the falling edge of the PWM signal is omitted.

At the same time t2 in FIG. 18, when the falling edge of the PWM signal is detected, the correction circuit 206 starts outputting the correction pulses and continues to output the correction pulses until the count value of the counter circuit 203 becomes a multiple of M=4. For example, at the time t2, if the count value of the counter circuit 203 is 2 (that is, the lower two bits are n<1>=1, n<0>=0), the correction circuit 206 continues to output the correction pulses until the count value of the counter circuit 203 becomes 4 (that is, the lower two bits are n<1>=n<0>=0), which is a multiple of M=4.

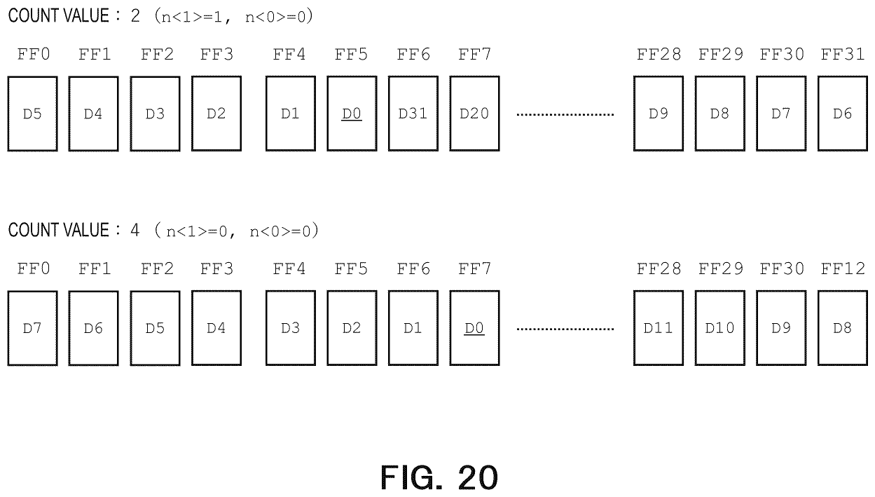

Therefore, the correction circuit 206 outputs 4−2=2 correction pulses. An upper part of FIG. 20 illustrates the count value of the counter circuit 203 and the internal state of the shift register circuit 201 before the correction pulses are output. A lower part of FIG. 20 illustrates the count value of the counter circuit 203 and the internal state of the shift register circuit 201 after the correction pulses are output.

At the time t3 in FIG. 18, when the rising edge (true rising edge) of the PWM signal is detected again, the pulse generation circuit 41 starts outputting the control pulses again from that timing. When the input of the control pulses from the pulse generation circuit 41 is started again, the electronic circuitry 200 starts outputting the data stored in the shift register circuit 201 again.

At this time, the electronic circuitry 200 does not start outputting from the continuation of the already output data, and outputs the 32 pieces of data in the predetermined order (D0, D1, . . . . D31) from the beginning again. Specifically, at the time t3, the count value of the counter circuit 203 is 4, and its upper three bits are n<4>=0, n<3>=0, and n<2>=1. Therefore, the selector circuit 204 selects the output of the seventh D-FF connected to its own first input port I<1> to be its own output OUT according to the truth table in FIG. 17.

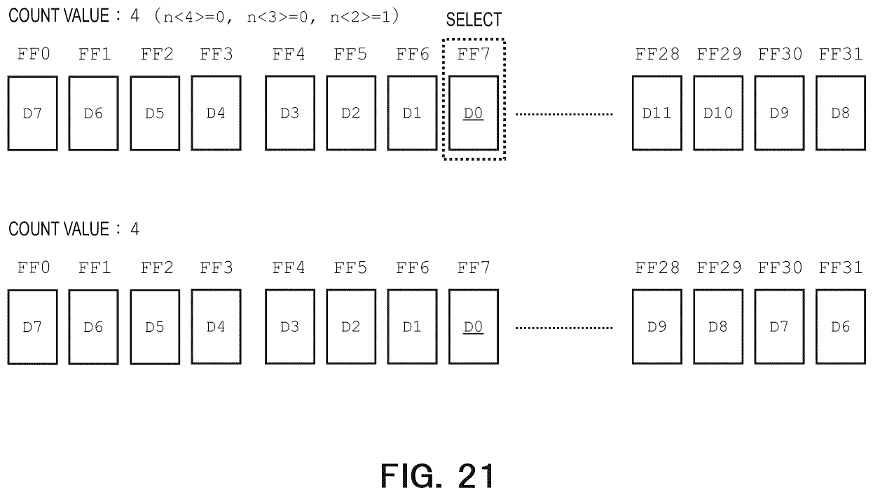

An upper part of FIG. 21 illustrates the count value of the counter circuit 203 and the internal state of the shift register circuit 201 at the time t3. As described above, since the selector circuit 204 selects the output of the seventh D-FF (FF7), the output of the FF7 becomes the output of the electronic circuitry 200. From this point on, the output of the FF7 changes in the order of D0, D1, . . . , D31 every time the control pulse is input. Therefore, every time the control pulse is input from the pulse generation circuit 41, the 32 pieces of data stored in the shift register circuit 201 are output piece by piece from the electronic circuitry 200 in the predetermined order (D0, D1, . . . . D31).

At the time t4 in FIG. 18, the pulse generation circuit 41 completes the output of the 32 control pulses. The electronic circuitry 200 completes the output of the 32 pieces of data. A lower part of FIG. 21 illustrates the count value of the counter circuit 203 and the internal state of the shift register circuit 201 at the time point at which the output of the 32 pieces of data is completed.

In this state, the count value of the counter circuit 203 is 4 and corresponds to the FF7 holding the leading data DO. Therefore, without resetting the counter circuit 203, it is possible to cope with the input of the next and subsequent control pulses in this state. In other words, there is no need to provide a reset mechanism in the counter circuit 203.

As described above, the electronic circuitry 200 according to the present embodiment 2 includes the correction circuit 206 that generates the correction pulses and outputs them to the shift register circuit 201. The correction circuit 206 starts outputting the correction pulses when the falling edge of the PWM signal is detected, and continues to output the correction pulses until the count value of the counter circuit 203 becomes a multiple of M=4.

In general, the number p of the correction pulses output from the correction circuit 206 can be expressed as follows, where q represents the number of the control pulses output due to abnormal pulses.

$$When Mod ( q / M ) = 0 p = 0 \qquad ( i )$$

$$When Mod ( q / M ) \neq 0 p = M - ( M ( q / M ) ) \qquad ( ii )$$

In the above expressions, Mod (q/M) means a remainder of q divided by M.

Alternatively, the number p of the correction pulses output from the correction circuit 206 can also be expressed as follows, where n represents the count value of the counter circuit 203 at the timing at which the falling edge of the PWM signal is detected.

$$When Mod ( n / M ) = 0 p = 0 \qquad ( i )$$

$$When Mod ( n / M ) \neq 0 p = M - ( Mod ( n / M ) ) \qquad ( ii )$$

In the above expressions, Mod (n/M) means a remainder of n divided by M.

Due to the above characteristics, in the present embodiment 2, compared to the embodiment 1 described earlier, the number of wires extending from the shift register circuit 201 to an outside, specifically the wires between the shift register circuit 201 and the selector circuit 204, can be significantly reduced. More specifically, compared to the embodiment 1, the number of the wires between the two can be reduced to 1/M. Thus, it is possible to significantly reduce a cost required for design and circuit mounting area.

In addition, in the above embodiment 2, by setting a frequency of the correction pulses higher than a frequency of the control pulses, it is possible to insert more correction pulses in a period between t2 and t3 in FIG. 18. Thus, it is possible to cope with not only the case when M=4, but also the cases when M=8, 16, 32, etc. A method to set the frequency of the correction pulses higher than the frequency of the control pulses is, for example, to input the clock signals of a frequency higher than that of the clock signals input to the correction circuit 206 in FIG. 16.

In general, a frequency fc of the correction pulses needs to satisfy the following relationship, with Tmin being a minimum pulse width of the PWM signal.

$$fc > M / T min$$

The minimum pulse width Tmin of the PWM signal is determined based on maximum and minimum values of the duty ratio of the PWM signal, a minimum pulse width of an unillustrated isolator inserted in a preceding stage of a PWM input of the drive circuit 40 in FIG. 2, and input capacitance, a load current, and a power supply voltage of the switching element 31 or the like.

### Embodiment 3

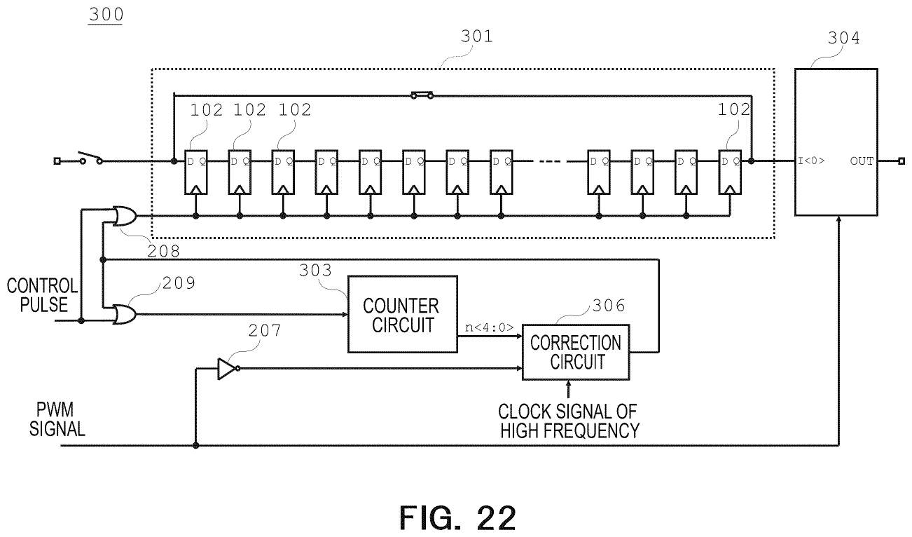

FIG. 22 is a diagram illustrating a configuration of an electronic circuitry 300 according to the embodiment 3. The electronic circuitry 300 includes a 32-bit shift register circuit 301, a counter circuit 303, a buffer circuit 304, and a correction circuit 306. When the rising edge of the PWM signal is detected, the buffer circuit 304 takes the output of the 31st D-FF 102 connected to its own input port I<0> as its own output OUT.

In the present embodiment 2 described earlier, out of the N=32 D-FFs 102 included in the shift register circuit 201, M=4 are grouped together, and only the output of one from each group of four is connected to the selector circuit 204. In contrast, in the present embodiment 3, only the output of a specific one of the N=32 D-FFs 102 included in the shift register circuit 301, specifically only the output of the 31st D-FF 102, is connected to the input port I<0> of the buffer circuit 304.

The detailed configuration of the counter circuit 303 is the same as that of the counter circuits 103 and 203 in the embodiments 1 and 2 (see FIG. 7). The counter circuit 303 counts the sum of the number of the control pulses and the number of the correction pulses input to the shift register circuit 301.

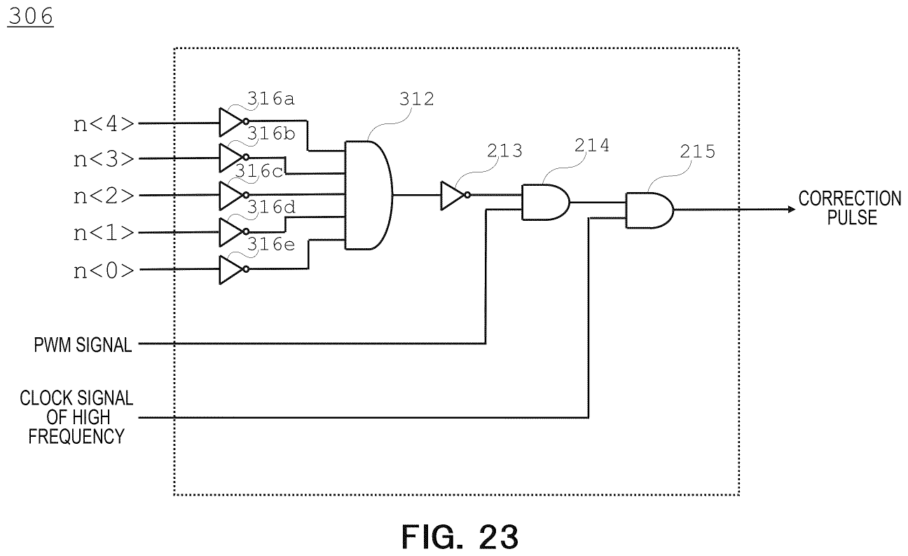

FIG. 23 is a diagram illustrating a detailed configuration of the correction circuit 306. The correction circuit 306 receives all the bits (n<4: 0>) of the count value of the pulse counter circuit 303, the PWM signal, and the clock signals of the frequency higher than that of the clock signals input to the pulse generation circuit 41. The correction circuit 306 is formed of NOT gates 316a-316e, an AND gate 312, the NOT gate 213, the AND gate 214, and the AND gate 215. With such a configuration, the correction circuit 306 starts outputting the correction pulses when the “falling edge” of the PWM signal is detected, and continues to output the correction pulses until the count value of the counter circuit 303 becomes an initial value 0.

Next, the operation when an unintended abnormal pulse is generated in the PWM signal in the electronic circuitry 300 according to the present embodiment 3 will be described. The normal operation is the same as that in the embodiments 1 and 2 described earlier so that the description is omitted.

(Operation when Unintended Abnormal Pulse is Generated in PWM Signal)

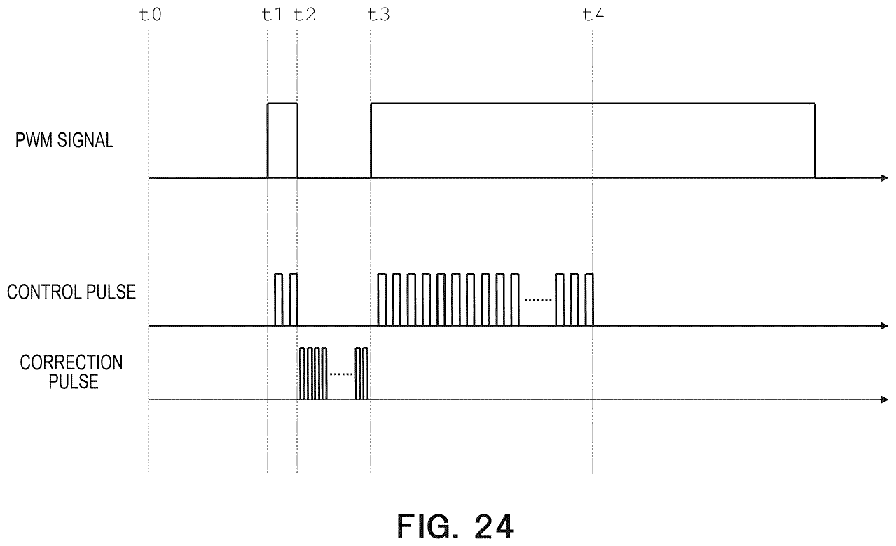

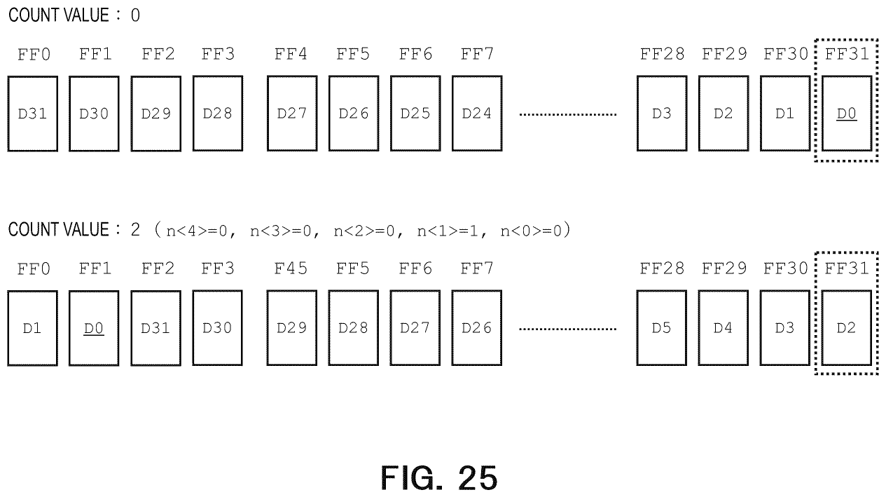

In the initial state at the time to in FIG. 24, the shift register circuit 301 of the electronic circuitry 300 stores the 32 pieces of data (D0, D1, . . . . D31) in the predetermined order. An upper part of FIG. 25 illustrates the count value of the pulse counter circuit 303 and the internal state of the shift register circuit 301 in the initial state at the time to.

At the time t1 in FIG. 24, when the rising edge (false rising edge) of the PWM signal due to an unintended abnormal pulse is detected, the pulse generation circuit 41 starts outputting the control pulses. When the input of the control pulses from the pulse generation circuit 41 is started, the electronic circuitry 300 starts outputting the data stored in the shift register circuit 301.

In detail, the output OUT of the buffer circuit 304 is the output of the 31st D-FF connected to its own input port I<0> at all times. Therefore, every time the control pulse is input from the pulse generation circuit 41, the data stored in the shift register circuit 301 is output piece by piece from the electronic circuitry 300 in the predetermined order (D0, D1, . . . ).

At the time t2 in FIG. 24, when the falling edge of the PWM signal is detected, the pulse generation circuit 41 starts outputting the control pulses again from that timing. However, the control pulses output at this time are input not to the electronic circuitry 300 currently being described but to a different electronic circuitry that stores the waveform data at the time of the turn-off. In FIG. 24, the control pulse output at the falling edge of the PWM signal is omitted.

At the same time t2 in FIG. 24, when the falling edge of the PWM signal is detected, the correction circuit 306 starts outputting the correction pulses and continues to output the correction pulses until the count value of the counter circuit 303 returns to the initial value 0. For example, at the time t2, if the count value of the counter circuit 303 is 2 (n<4>=0, n<3>=0, n<2>=0, n<1>=1, n<0>=0), the correction circuit 306 continues to output the correction pulses until the count value of the counter circuit 303 returns to the initial value 0 (n<4>=n<3>=n<2>=n<1>=n<0>=0).

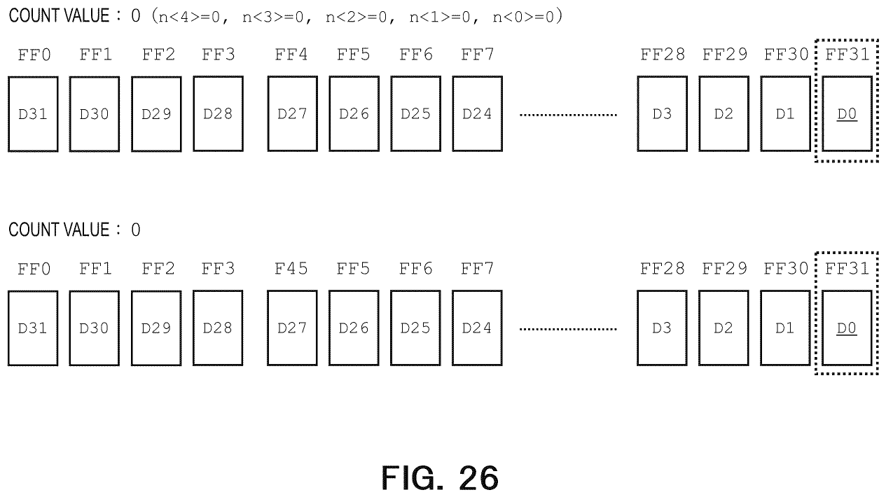

Therefore, the correction circuit 306 outputs 32−2=30 correction pulses. A lower part of FIG. 25 illustrates the count value of the counter circuit 303 and the internal state of the shift register circuit 301 before the correction pulses are output. An upper part of FIG. 26 illustrates the count value of the counter circuit 303 and the internal state of the shift register circuit 301 after the correction pulses are output.

At the time t3 in FIG. 24, when the rising edge (true rising edge) of the PWM signal is detected again, the pulse generation circuit 41 starts outputting the control pulses again from that timing. When the input of the control pulses from the pulse generation circuit 41 is started again, the electronic circuitry 300 starts outputting the data stored in the shift register circuit 301 again.

At this time, the internal state of the shift register circuit 301 is back to the same initial state as the upper part of FIG. 25. In addition, the count value of the counter circuit 303 is also back to the initial value 0. Therefore, every time the control pulse is input from the pulse generation circuit 41, the 32 pieces of data stored in the shift register circuit 301 are output piece by piece from the electronic circuitry 300 in the predetermined order (D0, D1, . . . . D31).

At the time t4 in FIG. 24, the pulse generation circuit 41 completes the output of the 32 control pulses. The electronic circuitry 300 completes the output of the 32 pieces of data. A lower part of FIG. 26 illustrates the count value of the counter circuit 303 and the internal state of the shift register circuit 301 at the time point at which the output of the 32 pieces of data is completed.

In this state, the count value of the counter circuit 303 is back to the initial value 0. Therefore, without resetting the counter circuit 303, it is possible to cope with the input of the next and subsequent control pulses in this state. In other words, there is no need to provide a reset mechanism in the counter circuit 303.

As described above, the electronic circuitry 300 according to the present embodiment 3 includes the shift register circuit 301 including the N=32 D-FFs 102, the correction circuit 306 that generates the correction pulses and outputs them to the shift register circuit 301, and the counter circuit 303 that counts the sum of the number of the control pulses generated based on the PWM signal and input to the shift register circuit 301 and the number of the correction pulses.

The counter circuit 303 counts N=32 integer values. The correction circuit 306 starts outputting the correction pulses when the falling edge of the PWM signal is detected, and continues to output the correction pulses until the count value of the counter circuit 303 returns to the initial value 0.

Due to the above characteristics, in the present embodiment 3, compared to the embodiments 1 and 2 described earlier, the number of wires extending from the shift register circuit 301 to the outside, specifically the wires between the shift register circuit 301 and the buffer circuit 304, can be further reduced. Thus, it is possible to further reduce the cost required for design and the circuit mounting area.

In the present embodiment 3, the number p of the correction pulses output from the correction circuit 306 can be expressed as follows, with q being the number of the control pulses output due to abnormal pulses.

$$When Mod ( q / N ) = 0 p = 0 \qquad ( i )$$

$$When Mod ( q / N ) \neq 0 p = N - ( Mod ( q / N ) ) \qquad ( ii )$$

In the above expressions, Mod (q/N) means a remainder of q divided by N.

Alternatively, the number p of the correction pulses output from the correction circuit 306 can also be expressed as follows, with n being the count value of the counter circuit 303 at the timing at which the falling edge of the PWM signal is detected.

$$When Mod ( n / N ) = 0 p = 0 \qquad ( i )$$

$$When Mod ( n / N ) \neq 0 \\ p = N - ( Mod ( n / N ) ) \qquad ( ii )$$

In the above expressions, Mod (n/N) means a remainder of n divided by N.

In addition, in the above embodiment 3, the frequency fc of the correction pulses needs to satisfy the following relationship, with Tmin being the minimum pulse width of the PWM signal.

$$f c > N / T min$$

The minimum pulse width Tmin of the PWM signal is determined based on the maximum and minimum values of the duty ratio of the PWM signal, the minimum pulse width of the unillustrated isolator inserted in the preceding stage of the PWM input of the drive circuit 40 in FIG. 2, and the input capacitance, the load current, and the power supply voltage of the switching element 31 or the like.

### (Modification)

In the above embodiments 1-3, the three-phase inverter circuit 30 is formed of the switching element 31. Instead, for example, a converter circuit may be formed of switching elements and diodes.

Further, the switching element 31 is not limited to a MOSFET. For example, the switching element 31 may be an IGBT. Alternatively, the switching element 31 may be a BJT (Bipolar Junction Transistor).

In addition, various materials such as Si (Silicon), SiC (Silicon Carbide), or GaN (Gallium Nitride) can be used as a semiconductor forming the switching element 31.

Note that the present invention is not limited to the embodiments as described above, and can be embodied by modifying components without departing from its spirit at the implementation stage. In addition, various inventions can be formed by appropriate combinations of a plurality of components disclosed in the above-described embodiments. For example, some components may be deleted from all the components shown in the embodiments. Furthermore, components from different embodiments may be appropriately combined.

The embodiments of the present invention can also be configured as follows.

### CLAUSES

### [1] (Embodiments 1 and 2)

Clause 1. An electronic circuitry comprising:
   a shift register circuit including a plurality of charge holding circuits;
   a counter circuit configured to count a number of control pulses input to the shift register circuit, which are generated based on a control signal; and
   a selector circuit configured to select one of outputs of the plurality of charge holding circuits based on the control signal and a count value of the counter circuit.

### [2] (Embodiments 1 and 2)

Clause 2. The electronic circuitry according to clause 1,
   wherein the shift register circuit includes N charge holding circuits,
   the counter circuit counts N integer values, and
   the selector circuit selects the output of the charge holding circuit corresponding to the count value of the counter circuit at a timing when a state of the control signal changes.

### [3] (Embodiment 1)

Clause 3. The electronic circuitry according to clause 1 or 2,
   wherein the shift register circuit includes the charge holding circuits from 0th to N-1th,
   the counter circuit counts integer values from 0 to N-1, and
   the selector circuit selects the output of an n-th charge holding circuit, where n represents the count value of the counter circuit at a timing when a state of the control signal change.

### [4] (Embodiment 1)

Clause 4. The electronic circuitry according to one of clauses 1 to 3,
   wherein all the outputs of the plurality of charge holding circuits are connected to the selector circuit.

### [5] (Embodiment 2)

Clause 5. The electronic circuitry according to clause 1 or 2, the electronic circuitry further comprising a correction circuit configured to generate correction pulses and to output the correction pulses to the shift register circuit,
   wherein the counter circuit counts a sum of a number of the control pulses and a number of the correction pulses input to the shift register circuit,
   the shift register circuit includes N charge holding circuits, where N is a multiple of a positive integer M, and
   the correction circuit starts outputting the correction pulses in response to a state of the control signal changing, and continues to output the correction pulses until the count value of the counter circuit becomes a multiple of the positive integer M.

### [6] (Embodiment 2)

Clause 6. The electronic circuitry according to clause 5,
   wherein M charge holding circuits out of the N charge holding circuits are grouped together, and only the output of one from each group of M charge holding circuits is connected to the selector circuit.

### [7] (Embodiment 2)

Clause 7. The electronic circuitry according to clause 5 or 7,
   wherein the correction circuit operates based on lower bits of the count value of the counter circuit.

### [8] (Embodiment 2)

Clause 8. The electronic circuitry according to one of clauses 5 to 7,
   wherein the selector circuit operates based on upper bits of the count value of the counter circuit.

### [9] (Embodiment 2)

Clause 9. The electronic circuitry according to one of clauses 5 to 8,
   wherein the counter circuit counts integer values from 0 to N-1, and
   a number p of the correction pulses output from the correction circuit is expressed as follows,

$$when Mod ( q / M ) = 0 p = 0 , and \qquad ( i )$$

$$when Mod ( q / M ) \neq 0 p = M - ( Mod ( q / M ) ) \qquad ( ii )$$

where q represents a number of the control pulses which are output due to an abnormal pulse generated in the control signal.

### [10] (Embodiment 2)

Clause 10. The electronic circuitry according to one of clauses 5 to 9,
   wherein the counter circuit counts integer values from 0 to N-1, and
   a number p of the correction pulses output from the correction circuit is expressed as follows,

$$when Mod ( n / M ) = 0 p = 0 , and \qquad ( i )$$

$$when Mod ( n / M ) \neq 0 p = M - ( Mod ( n / M ) ) \qquad ( ii )$$

where n represents the count value of the counter circuit.

### [11] (Embodiment 2)

Clause 11. The electronic circuitry according to one of clauses 5 to 10,
   wherein a frequency of the correction pulses is higher than a frequency of the control pulses.

### [12] (Embodiment 2)

Clause 12. The electronic circuitry according to one of clauses 5 to 11,
   wherein a frequency fc of the correction pulses satisfies a relationship of

$$fc > M / T min$$

where Tmin represents a minimum pulse width of the control signal.

### [13] (Embodiment 3)

Clause 13. An electronic circuitry comprising:
a shift register circuit including N charge holding circuits;
   a correction circuit configured to generate correction pulses and to output the correction pulses to the shift register circuit; and
   a counter circuit configured to count a sum of a number of control pulses input to the shift register circuit and a number of the correction pulses, the control pulses being generated based on a control signal and
   wherein the counter circuit counts N integer values, and
   the correction circuit is configured to start outputting the correction pulses in response to the state of the control signal changing, and continue to output the correction pulses until a count value of the counter circuit returns to an initial value.

### Embodiment 3

Clause 14. The electronic circuitry according to clause 13, the electronic circuitry further comprising a buffer circuit connected to an output of specific one of the N charge holding circuits,
   wherein the buffer circuit takes the output of the specific one of the N charge holding circuits in response to the state of the control signal changing, the buffer circuit outputs the taken output.

### [15] (Embodiment 3)

Clause 15. The electronic circuitry according to clause 13 or 14,
   wherein a frequency of the correction pulses is higher than a frequency of the control pulses.

### [16] (Embodiment 3)

Clause 16. The electronic circuitry according to one of clauses 13 to 15,
   wherein a frequency fc of the correction pulses satisfies a relationship of

$$fc > N / T min$$

where Tmin represents a minimum pulse width of the control signal.

### (a Drive Circuit)

Clause 17. A drive circuit comprising:
   a pulse generation circuit configured to generate and output control pulses based on a control signal;
   an electronic circuitry configured to sequentially receive the control pulses and to sequentially output waveform data in synchronization with the control pulses; and
   a signal generation circuit configured to generate a drive signal of a switching element based on the waveform data,
   wherein the electronic circuitry includes
   a shift register circuit including a plurality of charge holding circuits,
   a counter circuit configured to count a number of the control pulses input to the shift register circuit, and
   a first selector circuit configured to select one of outputs of the plurality of charge holding circuits based on the control signal and a count value of the counter circuit.

### [18] (a Drive Circuit)

Clause 18. The drive circuit according to clause 17, further comprising:
   the plurality of electronic circuitries;
   a second selector circuit configured to input the control pulses output from the pulse generation circuit to one of the plurality of electronic circuitries based on a selection signal; and
   a third selector circuit configured to input the waveform data output from one of the plurality of electronic circuitries to the signal generation circuit based on the selection signal.

### [19] (a Control System)

Clause 19. A control system comprising:
   a pulse generation circuit configured to generate and output control pulses based on a control signal;
   a plurality of electronic circuitries configured to sequentially receive the control pulses and to sequentially output waveform data in synchronization with the control pulses;
   a second selector circuit configured to input the control pulses output from the pulse generation circuit to one of the plurality of electronic circuitries based on a selection signal;
   a third selector circuit configured to acquire the waveform data output from one of the plurality of electronic circuitries based on the selection signal;
   a signal generation circuit configured to generate a drive signal of a switching element based on the waveform data acquired by the third selector circuit;
   a detection circuit configured to detect an operating state of the switching element; and
   a control circuit configured to generate the control signal and the selection signal based on the operating state,
   wherein the electronic circuitry includes
   a shift register circuit including a plurality of charge holding circuits,
   a counter circuit configured to count a number of the control pulses input to the shift register circuit, and
   a first selector circuit configured to select one of outputs of the plurality of charge holding circuits based on the control signal and a count value of the counter circuit.

1. An electronic circuitry comprising:
a shift register circuit including a plurality of charge holding circuits;
a counter circuit configured to count a number of control pulses input to the shift register circuit, which are generated based on a control signal; and
a selector circuit configured to select one of outputs of the plurality of charge holding circuits based on the control signal and a count value of the counter circuit.

2. The electronic circuitry according to claim 1,
wherein the shift register circuit includes N charge holding circuits,
the counter circuit counts N integer values, and
the selector circuit selects the output of the charge holding circuit corresponding to the count value of the counter circuit at a timing when a state of the control signal changes.

3. The electronic circuitry according to claim 1,
wherein the shift register circuit includes the charge holding circuits from 0th to N-1th,
the counter circuit counts integer values from 0 to N-1, and
the selector circuit selects the output of an n-th charge holding circuit, where n represents the count value of the counter circuit at a timing when a state of the control signal change.

4. The electronic circuitry according to claim 1,
wherein all the outputs of the plurality of charge holding circuits are connected to the selector circuit.

5. The electronic circuitry according to claim 1, the electronic circuitry further comprising a correction circuit configured to generate correction pulses and to output the correction pulses to the shift register circuit,
wherein the counter circuit counts a sum of a number of the control pulses and a number of the correction pulses input to the shift register circuit,
the shift register circuit includes N charge holding circuits, where N is a multiple of a positive integer M, and
the correction circuit starts outputting the correction pulses in response to a state of the control signal changing, and continues to output the correction pulses until the count value of the counter circuit becomes a multiple of the positive integer M.

6. The electronic circuitry according to claim 5,
wherein M charge holding circuits out of the N charge holding circuits are grouped together, and only the output of one from each group of M charge holding circuits is connected to the selector circuit.

7. The electronic circuitry according to claim 5,
wherein the correction circuit operates based on lower bits of the count value of the counter circuit.

8. The electronic circuitry according to claim 5,
wherein the selector circuit operates based on upper bits of the count value of the counter circuit.

9. The electronic circuitry according to claim 5,
wherein the counter circuit counts integer values from 0 to N-1, and
a number p of the correction pulses output from the correction circuit is expressed as follows,
$$when Mod ( q / M ) = 0 p = 0 , and \qquad ( i )$$
$$when Mod ( q / M ) \neq 0 p = M - ( Mod ( q / M ) ) \qquad ( ii )$$
where q represents a number of the control pulses which are output due to an abnormal pulse generated in the control signal.

10. The electronic circuitry according to claim 5,
wherein the counter circuit counts integer values from 0 to N-1, and
a number p of the correction pulses output from the correction circuit is expressed as follows,
$$when Mod ( n / M ) = 0 p = 0 , and \qquad ( i )$$
$$when Mod ( n / M ) \neq 0 p = M - ( Mod ( n / M ) ) \qquad ( ii )$$
where n represents the count value of the counter circuit.

11. The electronic circuitry according to claim 5,
wherein a frequency of the correction pulses is higher than a frequency of the control pulses.

12. The electronic circuitry according to claim 5,
wherein a frequency fc of the correction pulses satisfies a relationship of
$$fc > M / T min$$
where Tmin represents a minimum pulse width of the control signal.

13. An electronic circuitry comprising:
a shift register circuit including N charge holding circuits;
a correction circuit configured to generate correction pulses and to output the correction pulses to the shift register circuit; and
a counter circuit configured to count a sum of a number of control pulses input to the shift register circuit and a number of the correction pulses, the control pulses being generated based on a control signal and
wherein the counter circuit counts N integer values, and
the correction circuit is configured to start outputting the correction pulses in response to the state of the control signal changing, and continue to output the correction pulses until a count value of the counter circuit returns to an initial value.

14. The electronic circuitry according to claim 13, the electronic circuitry further comprising a buffer circuit connected to an output of specific one of the N charge holding circuits,
wherein the buffer circuit takes the output of the specific one of the N charge holding circuits in response to the state of the control signal changing, the buffer circuit outputs the taken output.

15. The electronic circuitry according to claim 13,
wherein a frequency of the correction pulses is higher than a frequency of the control pulses.

16. The electronic circuitry according to claim 13,
wherein a frequency fc of the correction pulses satisfies a relationship of
$$fc > N / T min$$
where Tmin represents a minimum pulse width of the control signal.

17. A drive circuit comprising:
a pulse generation circuit configured to generate and output control pulses based on a control signal;
an electronic circuitry configured to sequentially receive the control pulses and to sequentially output waveform data in synchronization with the control pulses; and
a signal generation circuit configured to generate a drive signal of a switching element based on the waveform data,
wherein the electronic circuitry includes
a shift register circuit including a plurality of charge holding circuits,
a counter circuit configured to count a number of the control pulses input to the shift register circuit, and
a first selector circuit configured to select one of outputs of the plurality of charge holding circuits based on the control signal and a count value of the counter circuit.

18. The drive circuit according to claim 17, further comprising:
the plurality of electronic circuitries;
a second selector circuit configured to input the control pulses output from the pulse generation circuit to one of the plurality of electronic circuitries based on a selection signal; and
a third selector circuit configured to input the waveform data output from one of the plurality of electronic circuitries to the signal generation circuit based on the selection signal.

19. A control system comprising:
a pulse generation circuit configured to generate and output control pulses based on a control signal;
a plurality of electronic circuitries configured to sequentially receive the control pulses and to sequentially output waveform data in synchronization with the control pulses;
a second selector circuit configured to input the control pulses output from the pulse generation circuit to one of the plurality of electronic circuitries based on a selection signal;
a third selector circuit configured to acquire the waveform data output from one of the plurality of electronic circuitries based on the selection signal;
a signal generation circuit configured to generate a drive signal of a switching element based on the waveform data acquired by the third selector circuit;
a detection circuit configured to detect an operating state of the switching element; and
a control circuit configured to generate the control signal and the selection signal based on the operating state,
wherein the electronic circuitry includes
a shift register circuit including a plurality of charge holding circuits,
a counter circuit configured to count a number of the control pulses input to the shift register circuit, and
a first selector circuit configured to select one of outputs of the plurality of charge holding circuits based on the control signal and a count value of the counter circuit.
